(19) United States
(12) Patent Application Publication
(10) Pub. No.: US 2009/0280753 A1
(43) Pub. Date: Nov. 12, 2009

(54) Method of Checking the Integrity of an Antenna Arrangement, Transmitter, Receiver and Transceiver

(75) Inventors: Melaine Philip, Orne (FR); Jean Luc Luong, Caen (FR); Klemens Breitfuss, Voitsberg (AT); Heimo Bergler, St. Ruprecht (AT); Erich Merlin, Gratkorn (AT)

Correspondence Address: NXP, B.V.;NXP INTELLECTUAL PROPERTY & LICENSING, M/S41-SJ, 1109 MCKAY DRIVE, SAN JOSE, CA, 95131, US

(73) Assignee: NXP B.V., Eindhoven (NL)

(21) Appl. No.: 12/306,018

(22) PCT Filed: May 25, 2007
(86) PCT No.: PCT/IB2007/051977

§ 371 Date: Dec. 22, 2008

(30) Foreign Application Priority Data
Jun. 21, 2006 (EP) 06300710.8

(51) Int. Cl. H04B 1/40; G01R 31/02; H04B 17/00

(52) U.S. Cl. 455/77; 324/537; 455/115.1

(57) ABSTRACT

In a method of checking the integrity of an antenna arrangement (2) of a transmitter (1), which transmitter (1) comprises a transmitter driving stage (4) for driving the antenna arrangement (2) with a driving current (is), a first value (I_{supply}) indicative of the driving current (iₛ) is determined. After that, it is detected whether the driving current (i) is outside a predefined current range by comparing the first value (I_{supply}) with a predefined first value range. If the first value (I_{supply}) is outside the first value range, then it is indicated that the antenna arrangement (2) is not in sound condition. The antenna arrangement (2) is comprised of an antenna (5) and a tuning network (6) connected between the antenna (5) and the transmitter driving stage (4).

### FIELD OF THE INVENTION

The invention relates to a method of checking the integrity of an antenna arrangement, to a transmitter, to a receiver, and to a transceiver.

### BACKGROUND OF THE INVENTION

A transmitter, a receiver or a transceiver comprises an antenna arrangement for sending and receiving signals, respectively. The antenna arrangement is comprised of an antenna, for instance, a loop or dipole antenna, and a tuning network connected between the antenna and a transmitter driving stage of the transmitter or connected between the antenna and a receiver stage of the receiver. The tuning network is, for instance, an LC-circuit, such as a matching circuit or an EMC (electro-magnetic-coupling) filter.

In order to operate correctly, the antenna arrangement must be attached correctly to the transmitter driving stage or to the receiver stage. Additionally, the tuning network should be assembled correctly, particularly the correct values for the electric devices as specified should be used for the tuning network.

Currently, the finally assembled antenna arrangement is only checked by means of a visual test. Then, a hardly visible disconnection within or wrongly used components for the tuning network can be overlooked, compromising the performance of the assembled transmitter or receiver.

Published international application for patent 03/049228 A1 discloses a method and an apparatus for checking integrity of a connectorized antenna. Instead of verifying the integrity of the antenna by a unique physical connector, the disclosed antenna has an additional resistor that has a value corresponding to antenna properties. When the antenna is connected to a transceiver, then a DC voltage of a predetermined voltage is applied across the resistor and a current flowing through the resistor is measured. The measured current correlates with the properties of the antenna. If the properties of the antenna obtained by the measured resistance of the resistors match the required characteristics of the antennas permissible to be attached to the transceiver, then the transceiver is allowed to transmit and receive signals. Otherwise, the transceiver is shut down.

### OBJECT AND SUMMARY OF THE INVENTION

It is an object of the invention to provide a method of checking the integrity of an antenna arrangement of a transmitter or a receiver, particularly for checking if a tuning network of the antenna arrangement is assembled correctly, which method is more reliable than the aforementioned visual test and which method is relatively simple to implement.

It is a further object of the invention to provide a transmitter, a receiver and a transceiver which have an embedded capability to detect a mismatched tuning network of its antenna arrangement or to detect a disconnection within the antenna arrangement.

The object of the invention is achieved by means of a method of checking the integrity of an antenna arrangement of a transmitter, which transmitter comprises a transmitter driving stage for driving the antenna arrangement with a driving current. The antenna arrangement is comprised of an antenna and a tuning network which is connected between the antenna and the transmitter driving stage. The method comprises the steps of:

determining a first value indicative of the driving current;

detecting whether the driving current is outside a predefined current range by comparing the first value with a predefined first value range; and

indicating that the antenna arrangement is not in sound condition if the first value is outside the first value range.

The inventive method is used to check if the antenna arrangement of the transmitter is assembled correctly or if a connection within the antenna arrangement is broken, i.e. in general if the antenna arrangement is in sound condition. In operation, the tuning network of the transmitter, which may particularly be a mobile phone or a reader for a transponder, is tuned to a tuning frequency that corresponds to a carrier frequency of the signals to be transmitted by the antenna. Then, the driving current generated by the transmitter driving stage and driving the antenna arrangement is within a certain range. The driving current is an AC current having the carrier frequency. This certain range may particularly be around the operating or nominal driving current. Consequently, the first value indicative of the driving current is within the predefined first value range if the antenna arrangement is in sound condition. If, for instance, the antenna is disconnected from the tuning network, then the driving current will differ significantly from the nominal driving current and the first value will be outside the first value range indicating that the antenna arrangement is not in sound condition.

If, for instance, the tuning network is disconnected from the transmitter driving stage, then the driving current will also differ significantly from the nominal driving current and the first value will also be outside the first value range also indicating that the antenna arrangement is not in sound condition. As a result, if the transmitter is operated at normal system operation and the antenna arrangement is in sound condition, then the driving current is within the predetermined current range which is around the nominal or operating driving current.

The same may be true if not the correct devices, such as appropriate valued inductors or capacitors, are used for the tuning network.

In order to especially detect a mismatched tuning network, the inventive method comprises, in a restricted version of the inventive method, the steps of:

determining a plurality of first values indicative of a plurality of driving currents, each related to an AC voltage of a plurality of AC voltages generated by the transmitter driving stage; the AC voltages having different frequencies;

detecting whether each of the first values is within a respective predefined first value range of a plurality of first value ranges; and

indicating that the antenna arrangement is not in sound condition if any of the first values is outside its predefined first value range.

The tuning network is comprised of several inductors and capacitors so that the antenna arrangement has an impedance. Then, the assembled transmitter can be tested by applying different AC voltages across the tuning network, each AC voltage having a different frequency. If the tuning network is assembled correctly, then each of the first values is within its respective predetermined first value range.

In order to have a satisfactory performance, the different frequencies of the AC voltages may be around the tuning frequency of the tuning network. Particularly, the AC voltages may be in a range between one tenth of the tuning frequency and twice the tuning frequency. This version of the inventive method is particularly useful for testing the assembled antenna arrangement for properly used devices for the tuning network. Especially, three to five different frequencies are utilized.

In one embodiment, the inventive method comprises the steps of:

determining a plurality of impedance values by dividing each of the AC voltages by the corresponding driving current;

detecting whether the plurality of impedance values match a plurality of predefined impedance values; and

indicating that the antenna arrangement is not in sound condition if the plurality of impedances does not match the plurality of predefined impedance values.

The transmitter driving stage generates the AC voltages, which results in the driving current of the antenna arrangement. A correctly assembled tuning network has a specific impedance characteristic. Thus, if the tuning network is assembled correctly, then the resulting impedance characteristic of the tested transmitter should match this specific or reference impedance characteristic. Utilizing the plurality of first values at different frequencies improves the reliability of the inventive method.

The transmitter driving stage is powered by a power supply with a supply current. In an embodiment of the inventive method, the electric current value of this supply current is utilized as the first value. The electric current value of the supply current may particularly be determined utilizing a current mirror circuit that copies the supply current. The mirrored current can then be further processed and may be compared with two threshold values corresponding to the predefined first value range. This version is particularly beneficial if the inventive method is incorporated into the transmitter, because only a few components have to be added to the existing designs.

The transmitter may be part of a transceiver. The transceiver comprises, in addition to the transmitter driving stage, a receiver stage. Then, the inventive method may further comprise the steps of:

determining a second value indicative of a voltage in the receiver stage at a predefined driving current;

detecting whether the voltage is outside a predefined voltage range by comparing the second value with a predefined second value range; and

indicating that the antenna arrangement is not in sound condition if the second value is outside the second value range.

Alternatively, the integrity of the antenna arrangement of the transceiver can be checked by only utilizing the voltage in the receiver stage, i.e. without utilizing the driving current.

The receiver stage is connected to the antenna arrangement and particularly to the tuning network. If the transceiver is in its sending mode, then the transmitter driving stage generates the driving current. The driving current will also cause the voltage to occur in the receiver stage. The voltage in the receiver stage does not only depend on the specific driving current, but also on the tuning network. Thus, if the tuning network is mismatched, then the second value which is indicative of the voltage in the receiver stage is without the predefined second value range.

If the transceiver is a near field device, such as a reader for a transponder, then the transceiver is likely to comprise an RF-level detector measuring the voltage on the output of the receiver stage. Then, the voltage detected by the RF-level detector may be used as the second value.

In order to improve reliability, the inventive method may comprise the steps of:

determining a plurality of second values indicative of a plurality of voltages in the receiver stage, each voltage having a frequency of a plurality of predetermined frequencies and/or each voltage being associated with different driving current values;

detecting whether each of the second values is within a respective predefined second value range of a plurality of second value ranges; and

indicating that the antenna arrangement is not in sound condition if any of the second values is outside its predefined second value range.

Thus, if the resulting voltage characteristic matches a predefined voltage characteristic associated with the correctly assembled tuning network, then the correct values are used for the tuning network.

The object is also achieved in accordance with the invention by means of a method of checking the integrity of an antenna arrangement of a receiver, which receiver comprises an antenna arrangement being comprised of a tuning network and an antenna configured to capture a signal in response to an electromagnetic signal and a receiver stage for processing the signal captured by the antenna; the tuning network being connected between the receiver stage and the antenna and the method comprising the steps of:

determining a value indicative of a voltage of the tuning network at a predefined field strength of the electromagnetic field;

detecting whether the voltage is outside a predefined voltage range by comparing the value with a predefined value range; and

indicating that the antenna arrangement is not in sound condition if the value is outside the value range.

This method can particularly be used for a receiver without transmission capability.

The object is also achieved in accordance with the invention by means of a transmitter comprising: an antenna arrangement being comprised of a tuning network and an antenna, a transmitter driving stage for driving the antenna arrangement with a driving current, wherein the tuning network is connected between the transmitter driving stage and the antenna, and a circuit for determining a first value indicative of the driving current, wherein the transmitter is configured to detect whether the driving current is outside a predefined current range by comparing the first value with a predefined first value range.

The inventive transmitter is thus configured to have the capability to carry out the inventive method.

The object is also achieved in accordance with the invention by means of a transceiver which comprises the inventive transmitter, a receiver stage, and a circuit for determining a second value indicative of a voltage in the receiver stage at a predefined driving current. The transceiver is configured to detect whether the voltage is outside a predefined voltage range by comparing the second value with a predefined second value range.

The object is also achieved in accordance with the invention by means of a receiver comprising: an antenna arrangement being comprised of a tuning network and an antenna. The antenna is configured to capture a signal in response to an electromagnetic signal. The receiver further comprises a receiver stage for processing the signal captured by the antenna, wherein the tuning network is connected between the receiver stage and the antenna, and a circuit for determining a value indicative of the voltage, wherein the receiver is configured to detect, at a predefined field strength of the electromagnetic field, whether the voltage is outside a predefined voltage range by comparing the value with a predefined value range.

The object is also achieved in accordance with the invention by means of a transceiver comprising: an antenna arrangement being comprised of a tuning network and an antenna, a transmitter driving stage for driving the antenna arrangement with a driving current, wherein the tuning network is connected between the transmitter driving stage and the antenna, a receiver stage, and a circuit for determining a value indicative of a voltage in the receiver stage at a predefined driving current. The inventive transceiver is further configured to detect whether the voltage is outside a predefined voltage range by comparing the value with a predefined value range.

### BRIEF DESCRIPTION OF THE DRAWINGS

The invention will be described in greater detail hereinafter by way of non-limiting examples with reference to the embodiments shown in the drawings.

FIG. 1 is a block diagram of an exemplary transmitter with an antenna arrangement;

FIG. 2 is a circuit diagram of a circuit that detects whether the antenna arrangement of FIG. 1 is not in sound condition;

FIGS. 3 and 4 are flow charts which illustrate the detecting of the antenna arrangement of FIG. 1 not being in sound condition;

FIG. 5 is a block diagram of an exemplary transceiver with an antenna arrangement;

FIG. 6 is a flow chart which illustrates the detecting of a mismatched tuning circuit of the antenna arrangement of FIG. 5; and

FIG. 7 is a flow chart which illustrates the detecting of a mismatched tuning circuit of an antenna arrangement of a receiver.

### DESCRIPTION OF EMBODIMENTS

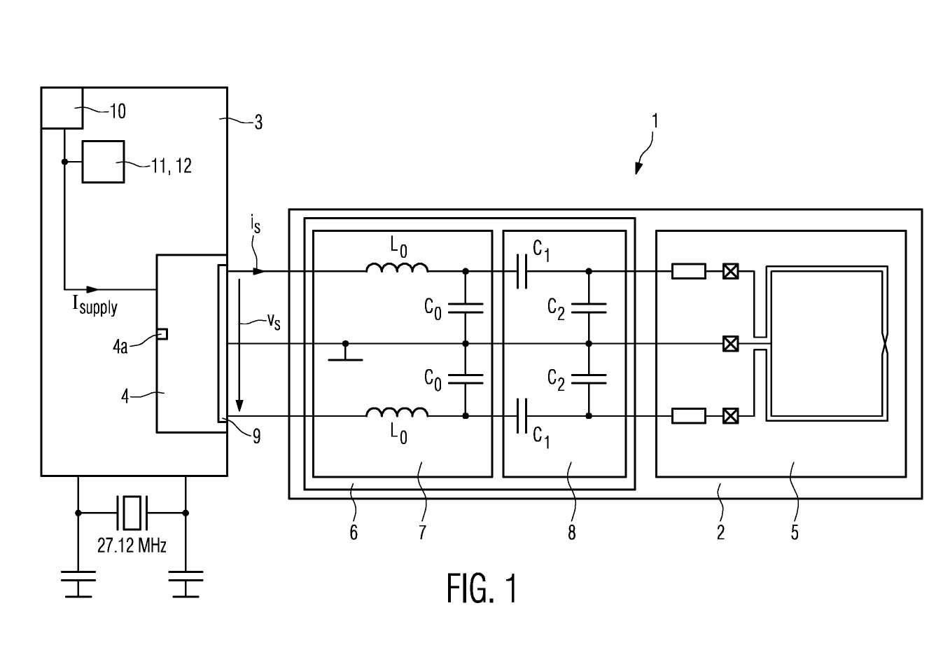

FIG. 1 is a block diagram of a transmitter 1 which is a reader for a near field communication (NFC) application for the exemplary embodiment. The transmitter 1 comprises an antenna arrangement 2 and a main transmitter circuit 3. For the exemplary embodiment, the antenna arrangement 2 is comprised of a loop antenna 5 and a tuning network 6 and the main transmitter circuit 3 comprises a transmitter driving stage 4. The tuning network 6 is an LC-network comprised of an electromagnetic coupling (EMC) filter 7 and a matching circuit 8 connected between the EMC filter 7 and the antenna 5. The tuning network 6 and particularly the matching circuit 8 are tuned to a certain tuning frequency f_{T}. The matching circuit 8 comprises a plurality of capacitors C₁-C₂ having values corresponding to the tuning frequency f_{T}. For the exemplary embodiment, the tuning frequency f_{T} is 14.1 MHz. The EMC filter 7 comprises a plurality of inductors L₀ and a plurality of capacitors C₀.

The transmitter driving stage 4 has an input 4a and an output 9. The output 9 of the transmitter driving stage 4 is connected to the antenna arrangement 2 and specifically to the EMC filter 7. The transmitter driving stage 4 receives, on its input 4a, data to be transmitted by the transmitter 1. The transmitter driving stage 4 generates a high-frequency voltage signal vₛ, which has a carrier frequency f_{C} of 13.56 MHz and is present at the output 9 of the transmitter driving stage 4 for the exemplary embodiment. The high-frequency voltage signal vₛ causes a driving current iₛ to exit from the output 9 of the transmitter stage 4 and flow into the antenna arrangement 2.

For the exemplary embodiment, the transmitter stage 4 is powered by a voltage source 10 providing a constant voltage V₀ and connected to the transmitter driving stage 4. The constant voltage V₀ is processed in a well-known manner by the transmitter driving stage 4 in order to generate a high-frequency carrier signal v_{c} having the carrier frequency f_{C}. In order to obtain the high-frequency voltage signal vₛ, the data fed to the input 4a are modulated with the high-frequency carrier signal v_{c} in a well-known manner.

When powering the transmitter driving stage 4, a supply current I_{supply} flows from the voltage source 10 to the transmitter driving stage 4. The supply current I_{supply} is approximately proportional to the driving current iₛ flowing into the antenna arrangement 2. As a result, the supply current I_{supply} is indicative of the driving current iₛ that flows into the antenna arrangement 2.

For the exemplary embodiment, the transmitter 1 comprises a current mirror circuit 11 which copies the supply current I_{supply}. For the exemplary embodiment, the current mirror circuit 11 generates two currents, each copying the supply current I_{supply}.

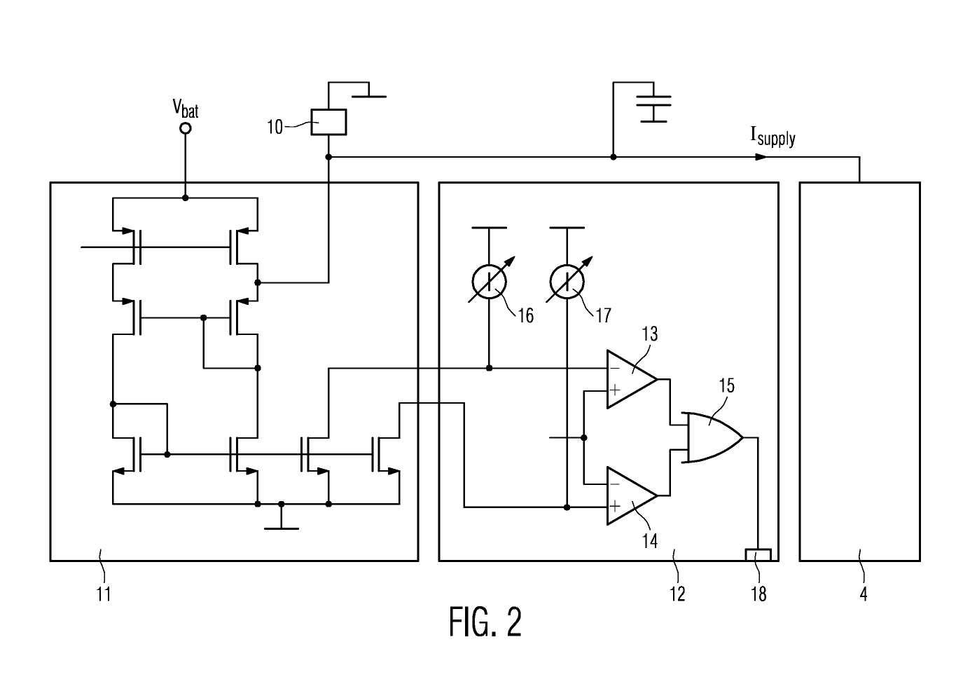

For the exemplary embodiment, the transmitter 1 further comprises an evaluation circuit 12 comprised of two comparators 13, 14, an AND-logic device 15, two current sources 16, 17 and an output 18. The purpose of the evaluation circuit 12 is to detect whether the supply current I_{supply} is outside a predetermined current range. The predetermined current range can be predetermined by adjusting the currents of the two current sources 16, 17 appropriately. If the supply current I_{supply} is outside the predetermined current range, then the output signal of the evaluation circuit 12 present at the output 18 of the evaluation circuit 12 is logical high. The current mirror circuit 11 and the evaluation circuit 12 are shown in FIG. 2.

The purpose of the evaluation circuit 12 is to inform a user of the transmitter 1 if the antenna arrangement 2 is not in sound condition. The antenna arrangement 2 is in sound condition, if the driving current iₛ within a predetermined current range around the nominal or operating driving current of the transmitter 1.

If the antenna 5 is disconnected from the matching circuit 8, then the transmitter stage 4 drives only the tuning circuit 6. As a result, the driving current iₛ greater than the nominal driving current.

If the matching circuit 8 is disconnected from the EMC filter 7, then the transmitter stage 4 drives only the EMC filter 7. As a result, the driving current iₛ greater than the nominal driving current.

If the entire antenna arrangement 2 is disconnected from the transmitter driving stage 4, then the driving current iₛ less than the nominal driving current.

Therefore, the currents of the current sources 16, 17 of the evaluation circuit 12 are chosen so that the evaluation circuit 12 detects if the supply current I_{supply} is outside a current range corresponding to a driving current range around the nominal driving current.

If the evaluation circuit 12 detects that the supply current I_{supply} is outside the predetermined current range, then the output signal of the evaluation circuit 12 present at the output 18 of the evaluation circuit 12 is logical high. This information can, for instance, be illustrated utilizing a LED (not shown in the figures).

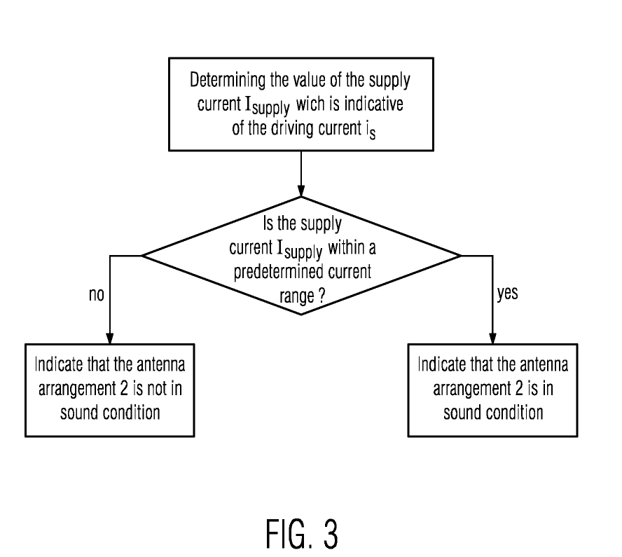

FIG. 3 illustrates the method how to detect when the antenna arrangement 2 of the transmitter 1 is not in sound condition. Firstly, the supply current I_{supply}, which is indicative of the driving current iₛ, is measured. If the supply current l_{supply} is within the predetermined current range, then it is indicated that the antenna arrangement 2 is in sound condition and particularly that a connection within the antenna arrangement 2 is not broken.

The transmitter 1 described so far is configured to compare the supply current I_{supply} with one predetermined current range particularly during operation of the transmitter 1.

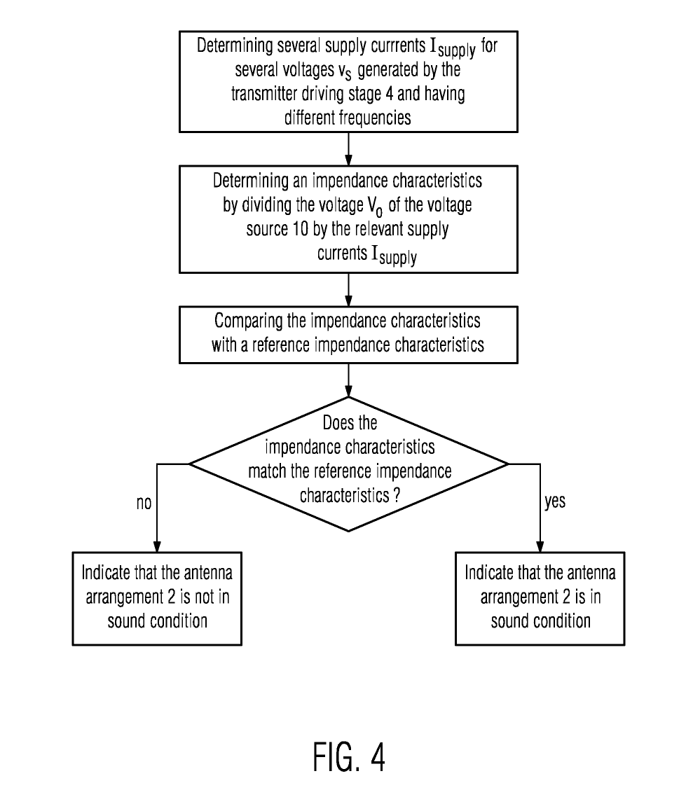

FIG. 4 is a flow chart illustrating a further embodiment of the inventive method.

The transmitter 1 can alternatively be operated to generate, at the output 9 of the transmitter driving stage 4, voltages vₛ having different frequencies. In response to the voltages vₛ having different frequencies, different driving currents iₛ also having different frequencies are flowing into the antenna arrangement 2. The resulting different driving currents iₛ can then be utilized to check if the tuning network 6 is matched correctly, i.e. if the correct values for the inductors L₀ and the capacitors C₀-C₂ are used.

The corresponding supply currents I_{supply} for the transmitter driving stage 4 are each approximately proportional to the relevant driving currents iₛ. For the exemplary embodiment, the corresponding supply currents I_{supply} are utilized as measurements of the relevant driving currents iₛ. The supply currents I_{supply} are determined by the mirror current circuit 11.

For the exemplary embodiment, an impedance characteristic for the transmitter 1 is then determined. The individual impedances of these characteristics are related to the relevant voltages vₛ at the output 9 of the transmitter driving stage 4 divided by the respective driving current iₛ. For the exemplary embodiment, the voltages vₛ generated by the transmitter driving stage 4 have approximately the form of a square wave signal with a peak value of V₀ of the voltage source 10. Additionally, the supply currents I_{supply} are approximately proportional to the respective driving currents iₛ. For the exemplary embodiment, the impedance characteristic is determined by dividing the voltage V₀ of the voltage source 10 by the relevant supply current I_{supply}.

For the exemplary embodiment, the carrier frequency f_{C} is 13.56 MHz and the different frequencies for the voltages vₛ at the output 9 of the transmitter driving stage 4 are within a range of 1 MHz and 27 MHz.

The determined impedance characteristic for the transmitter 1 is then compared with a reference impedance characteristic. The reference impedance characteristic is related to a tuning network that is comprised of inductors and capacitors with the correct values.

If this comparison yields a mismatch of the reference and the detected impedance characteristic, then the transmitter 1 or an external device indicates that the antenna arrangement 2 is not in sound condition and specifically that at least one of the inductors L₀ or the capacitors C₀-C₁ of the tuning network 6 has an incorrect value.

If the reference and the detected impedance characteristic match, then the transmitter 1 or the external device indicates that the antenna arrangement 2 is in sound condition.

Instead of utilizing the impedance characteristics, different driving currents iₛ for different voltages vₛ with different frequencies can be compared with respective reference current ranges. If each of the driving currents iₛ within its current range, then the antenna arrangement 2 is in sound condition.

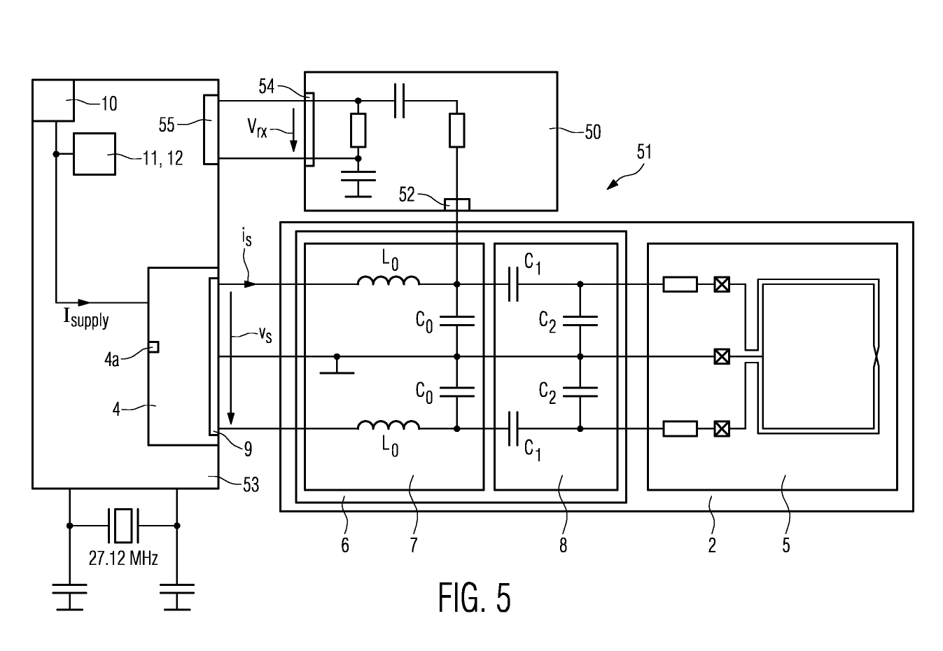

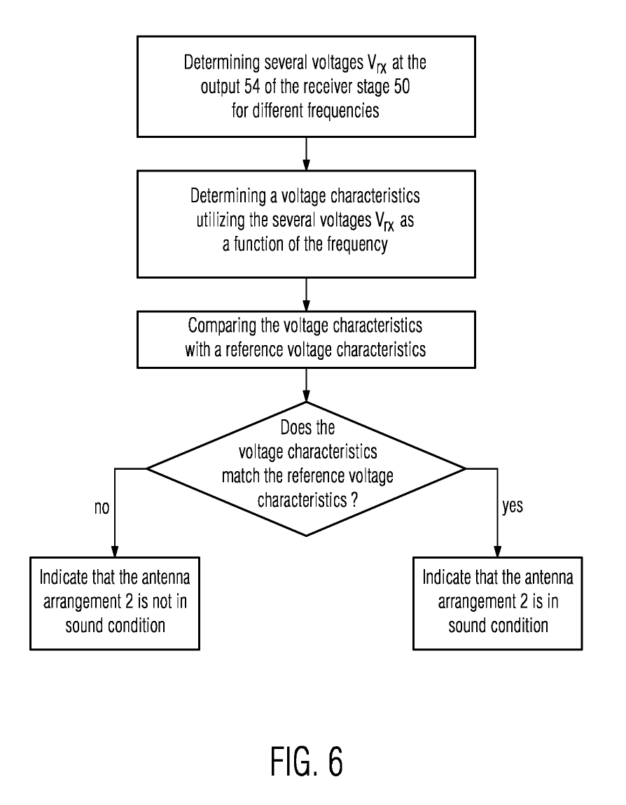

FIG. 5 shows an exemplary embodiment of an inventive transceiver 51 and FIG. 6 is a flow chart illustrating a further embodiment of the inventive method. If not indicated otherwise, then components of the transceiver 51 corresponding to components of the transmitter 1 are denoted by the same reference signs.

The transceiver 51 of FIG. 5 is basically comprised of the transmitter 1 of FIG. 1 and has an additional receiver stage 50. The receiver stage 50 has an input 52 and an output 54. The output 54 of the receiver stage 50 is connected to the main transceiver circuit 53 of the transceiver 51 and the input 52 is connected to the tuning network 6. The main transceiver circuit 53 comprises, for instance, the transmitter driving stage 4.

In order to improve the performance of the inventive method, the voltage Vᵣₓ at the output 54 of the receiver stage 50 is measured. For the exemplary embodiment, this is done by an RF-level detector 55 of the main transceiver circuit 53. The voltage Vᵣₓ is proportional to a voltage vᵣᵢ present on the input 52 of the receiver stage 50. For the exemplary embodiment, not only the aforementioned impedance characteristic for different frequencies is determined, but also a voltage characteristic having different voltage values Vᵣₓ as a function of the frequency is determined. This voltage characteristic is then compared with a reference voltage characteristic related to a reference tuning network whose inductors and capacitors have correct values. If the two voltage characteristics match, then it is indicated that the antenna arrangement 2 is in sound condition. If the two voltage characteristics do not match, then it is indicated that the antenna arrangement 2 is not in sound condition.

In addition, the decision that the antenna arrangement 2 is in sound condition can be based on both the impedance characteristic and the voltage characteristic. Then, it is only concluded that the antenna arrangement 2 is in sound condition, if both the impedance characteristic and the voltage characteristic match the reference impedance characteristic and the reference voltage characteristic, respectively.

For the methods described so far, the driving current iₛ, generated by the transmitter driving stage 4, is necessary. Thus, the described methods are applicable to transmitters and transceivers.

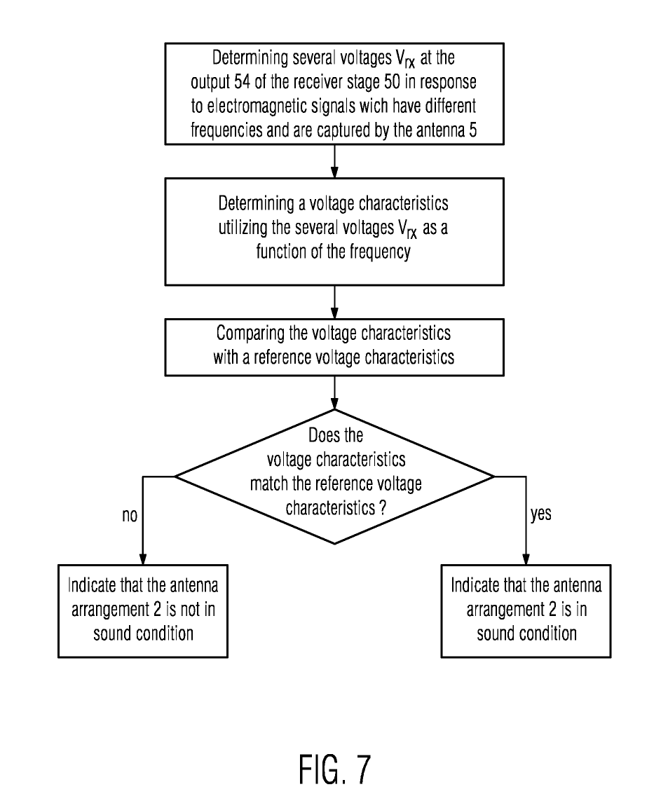

FIG. 7 shows a flow chart which illustrates in general the detecting of a mismatched tuning circuit of an antenna arrangement of a receiver. This method can also be used for the transceiver 51 when operating in its receiving mode.

When operating in its receiving mode, then the antenna 5 captures a signal transmitted by an electromagnetic signal. This electromagnetic signal generates a voltage vi on the input 52 of the receiver circuit 50 and thus a voltage Vᵣₓ at the output 54 of the receiver stage 50. In order to test the integrity of the antenna arrangement 2, the transceiver 51 is exposed to electromagnetic signals with different frequencies and a given field strength. The frequency range of the electromagnetic signals is between 1 Mhz and 27 MHz for the exemplary embodiment.

The detected voltage characteristic is compared with a reference voltage characteristic related to a reference antenna arrangement. If the voltage characteristics match, then it is indicated that the antenna arrangement 2 is in sound condition. Otherwise, it is indicated that the antenna arrangement is not in sound condition.

Finally, it should be noted that the above-mentioned embodiments illustrate rather than limit the invention, and that those skilled in the art will be capable of designing many alternative embodiments without departing from the scope of the invention as defined by the appended claims. In the claims, any reference signs placed in parentheses shall not be construed as limiting the claims. The words “comprising” and “comprises”, and the like, do not exclude the presence of elements or steps other than those listed in any claim or the specification as a whole. The singular reference of an element does not exclude the plural reference of such elements and vice versa. In a device claim enumerating several means, several of these means may be embodied by one and the same item of software or hardware. The mere fact that certain measures are recited in mutually different dependent claims does not indicate that a combination of these measures cannot be used to advantage.

1. A method of checking an integrity of an antenna arrangement of a transmitter, which transmitter comprises a transmitter driving stage for driving said antenna arrangement with a driving current; said antenna arrangement being comprised of an antenna and a tuning network connected between said antenna and said transmitter driving stage; the method comprising:
determining a first value indicative of said driving current;
detecting whether said driving current is outside a predefined current range by comparing said first value with a predefined first value range; and
indicating that said antenna arrangement is not in sound condition if said first value is outside said first value range.

2. The method of claim 1, further comprising,
determining a plurality of said first values indicative of a plurality of said driving currents, each related to an AC voltage of a plurality of AC voltages generated by said transmitter driving stage; said AC voltages having different frequencies;
detecting whether each of said first values is within a respective predefined first value range of a plurality of first value ranges; and
indicating that said antenna arrangement is not in sound condition if any of said first values is outside its predefined first value range.

3. The method of claim 2, further comprising,
determining a plurality of impedance values by dividing each of said AC voltages by the corresponding driving current;
detecting whether said plurality of impedance values match a plurality of predefined impedance values; and
indicating that said antenna arrangement is not in sound condition if any of said plurality of impedances does not match said plurality of predefined impedance values.

4. The method of claim 2, wherein said tuning network is tuned to a tuning frequency and said different frequencies of said AC voltages are in a range between one tenth of said tuning frequency and twice said tuning frequency.

5. The method of claim 1, further comprising the steps of:
powering said transmitter driving stage with a supply current,
utilizing the electric current value of said supply current as said first value; and
comparing said electric current value of said supply current with a predefined supply current range for detecting whether said driving current is outside said predefined current range.

6. The method of claim 1, wherein said transmitter is a transceiver, further comprising a receiver stage; the method further comprising,
determining a second value indicative of a voltage in said receiver stage at a predefined driving current;
detecting whether said voltage is outside a predefined voltage range by comparing said second value with a predefined second value range; and
indicating that said antenna arrangement is not in sound condition if said second value is outside said second value range.

7. The method of claim 6, further comprising.
determining a plurality of said second values indicative of a plurality of said voltages in said receiver stage, each voltage having a frequency of a plurality of predetermined frequencies and/or each voltage being associated with different values of said driving currents;
detecting whether each of said second values is within a respective predefined second value range of a plurality of second value ranges; and
indicating that said antenna arrangement is not in sound condition if any of said second values is outside its predefined second value range.

8. A method of checking an integrity of an antenna arrangement of a transceiver, which transceiver comprises a transmitter driving stage for driving said antenna arrangement with a driving current and a receiver stage; said antenna arrangement being comprised of an antenna and a tuning network connected between said antenna and said transmitter driving stage; the method comprising:
determining a value indicative of a voltage in said receiver stage at a predefined driving current;
detecting whether said voltage is outside a predefined voltage range by comparing said value with a predefined value range; and
indicating that said antenna arrangement is not in sound condition if said value is outside said value range.

9. The method of claim 8, further comprising,
determining a plurality of said values indicative of a plurality of said voltages in said receiver stage, each voltage having a frequency of a plurality of predetermined frequencies and/or each voltage being associated with different values of said driving currents;
detecting whether each of said values is within a respective predefined value range of a plurality of value ranges; and
indicating that said antenna arrangement is not in sound condition if any of said values is outside its predefined value range.

10. A method of checking the integrity of an antenna arrangement of a receiver, which receiver comprises an antenna arrangement being comprised of a tuning network and an antenna configured to capture a signal in response to an electromagnetic signal and a receiver stage for processing said signal captured by said antenna; said tuning network being connected between said receive stage and said antenna, the method comprising:
determining a value indicative of a voltage of said tuning network at a predefined field strength of said electromagnetic field;
detecting whether said voltage is outside a predefined voltage range by comparing said value with a predefined value range; and
indicating that said antenna arrangement is not in sound condition if said value is outside said value range.

11. A transmitter, comprising:
an antenna arrangement being comprised of a tuning network and an antenna;
a transmitter driving stage for driving said antenna arrangement with a driving current; said tuning network being connected between said transmitter driving stage and said antenna; and
a circuit for determining a first value indicative of said driving current; said transmitter being configured to detect whether said driving current is outside a predefined current range by comparing said first value with a predefined first value range.

12. The transmitter of claim 11, wherein said circuit for determining said first value is configured to determine a plurality of said first values indicative of a plurality of said driving currents, each related to an AC voltage of a plurality of AC voltages generated by said transmitter driving stage; said AC voltages having different frequencies; and
wherein said transmitter is configured to detect whether each of said first values is within a respective predefined first value range of a plurality of first value ranges.

13. The transmitter of claim 12, configured to determine a plurality of impedance values by dividing each of said AC voltages by the corresponding driving current; and
configured to detect whether said plurality of impedance values match a plurality of predefined impedance values.

14. The transmitter of claim 12, wherein said tuning network is tuned to a tuning frequency and said different frequencies of said AC voltages are in a range between one tenth of said tuning frequency and twice said tuning frequency.

15. The transmitter of claim 11, comprising a power supply powering said transmission driving stage with a supply current; the value of said supply current being utilized as said first value and said circuit for determining said first value indicative of said driving current being configured to mirror said supply current.

16. A transceiver, comprising:
a transmitter including an antenna arrangement being comprised of a tuning network and an antenna; a transmitter driving stage for driving said antenna arrangement with a driving current; said tuning network being connected between said transmitter driving stage and said antenna; and a circuit for determining a first value indicative of said driving current; said transmitter being configured to detect whether said driving current is outside a predefined current range by comparing said first value with a predefined first value range.
a receiver stage; and
a circuit for determining a second value indicative of a voltage in said receiver stage at a predefined driving current; said transceiver being configured to detect whether said voltage is outside a predefined voltage range by comparing said second value with a predefined second value range.

17. The transceiver of claim 16, wherein said circuit for determining said second value is configured to determine a plurality of said second values indicative of a plurality of said voltages in said receiver circuit; each voltage having a frequency of a plurality of predetermined frequencies and/or each voltage being associated with different of said driving currents
wherein said transceiver is configured to detect whether each of said second values is within a respective predefined second value range of a plurality of second value ranges.

18. A receiver, comprising:
an antenna arrangement being comprised of a tuning network and an antenna; said antenna being configured to capture a signal in response to an electromagnetic signal;
a receiver circuit for processing said signal captured by said antenna; said tuning network being connected between said receive circuit and said antenna; and
a circuit for determining a value indicative of a voltage of said tuning network; said receiver being configured to detect, at a predefined field strength of said electromagnetic field, whether said voltage is outside a predefined voltage range by comparing said value with a predefined value range.

19. A transceiver, comprising:
an antenna arrangement being comprised of a tuning network and an antenna;
a transmitter driving stage for driving said antenna arrangement with a driving current; said tuning network being connected between said transmitter driving stage and said antenna;
a receiver stage; and
a circuit for determining a value indicative of a voltage in said receiver stage at a predefined driving current; said transceiver being configured to detect whether said voltage is outside a predefined voltage range by comparing said value with a predefined value range.

20. The transceiver of claim 19, wherein said circuit for determining said value is configured to determine a plurality of said values indicative of a plurality of said voltage in said receiver circuit; each voltage having a frequency of a plurality of predetermined frequencies and/or each voltage being associated with different of said driving currents; and
wherein said transceiver is configured to detect whether each of said values is within a respective predefined value range of a plurality of value ranges.
